(19) United States
(12) Patent Application Publication
(10) Pub. No.: US 2026/0328828 A1
(43) Pub. Date: Oct. 22, 2026

(54) MAGNETIC PROBE FOR DETECTING DEFECTS IN CABLES WITH A FERROMAGNETIC PART, ASSOCIATED METHOD AND SYSTEM

(71) Applicants: HYDRO-QUÉBEC, Montréal (CA); POLYVALOR, LIMITED PARTNERSHIP, Quebec (CA)

(72) Inventors: Yahya IBEN BRAHIM, Trois-Rivières (CA); Jonathan BELLEMARE, Varennes (CA); Frédéric SIROIS, Montréal (CA); Gilles ROUSSEAU, Anjou (CA)

(21) Appl. No.: 19/105,987

(22) PCT Filed: Aug. 24, 2023
(86) PCT No.: PCT/CA2023/051119

§ 371 Date: Feb. 24, 2025

(30) Foreign Application Priority Data
Aug. 24, 2022 (CA) 3171364

(51) Int. Cl. G01R 31/08

(52) U.S. Cl. CPC G01R 31/085

(57) ABSTRACT

A magnetic probe for detecting defects in a ferromagnetic portion of a cable is provided. The probe includes at least three magnetic circuits held by a frame and each circuit includes a core configured to extend along the cable when the probe is in use; means for generating a magnetic flux in a section of the ferromagnetic portion of the cable; and an air gap located in the core to create a zero magnetic field point surrounded by a low magnetic field zone, between the core and the central axis. The probe includes at least three magnetic sensors, each associated with one or more circuits and located outside the core, in the low magnetic field zone. The sensors are capable of measuring a magnetic flux or a variation in the magnetic flux caused by defects in the ferromagnetic portion of the cable.

### TECHNICAL FIELD

The present application relates to the field of apparatuses and methods for detecting and locating one or more defects in components having at least one ferromagnetic part, and more particularly concerns a magnetic probe for detecting defects in cables including a ferromagnetic part.

### BACKGROUND

It is estimated that there are approximately 5 million kilometers of high-voltage power lines worldwide, to which approximately 200,000 km of new high-voltage power lines are added every year. To put this number in perspective, Hydro-Québec has the largest power network in North America, with 35,000 km of high-voltage lines, representing around 0.7% of the world total. A large proportion of the electrical conductors used on these high-voltage lines are of the ACSR (Aluminum Conductor Steel Reinforced) type or the AAAC (All Aluminum Alloy Conductors) type. In the case of network powered by Hydro-Québec, ACSR conductors are practically the only ones actively used. These consist of a central steel core, which ensures the conductor's mechanical strength. It generally comprises between 1 and 37 steel strands galvanized with zinc to resist corrosion and/or other external mechanical forces. At the periphery of the steel core, there are usually between 6 and 84 aluminum strands for electrical conduction. An example of such a conductor is shown in FIG. 3 (PRIOR ART). Finally, ACSR conductors are produced in finished lengths of the order of a kilometer, and must therefore be spliced together using connecting sleeves, also made of steel and aluminum.

Over a period of more than fifty years, or in the event of inadequate installation of the conductors, corrosion agents present in the environment can corrode the steel core and/or the connecting sleeves. Extreme weather conditions, such as, but not limited to, strong winds, ice and lightning, can damage electrical conductors, resulting in broken strands. In particular, strand breakage is associated with a loss of mechanical strength, which can ultimately lead to the breakage of the electrical conductor, and therefore, the high-voltage power line. To avoid this situation, non-destructive testing can be carried out with magnetic probes that use the Magnetic Flux Leakage (MFL) principle, such as the Magnetester, Intron or Magnetograph. These devices include detectors for Loss of Metallic Area (LMA) and Local Fault (LF). However, these devices are not suitable for ACSR conductors, but rather for cables made of steel only. More specifically, these devices either have too small of an opening for most ACSR conductors, or are too heavy to be easily transported, including by drone. Existing equipment and devices are unable to pass through connection sleeves, which limits their characterization.

In light of the above, there is therefore a need for a device, method and associated system to solve at least one of the problems and/or limitations discussed above.

### SUMMARY

In accordance with one aspect, there is provided a magnetic probe for detecting defects in a ferromagnetic part of a cable, the magnetic probe including: a frame having a central axis and a passage for passing the cable therethrough; at least three magnetic circuits held by the frame, each being spaced apart from one another, each magnetic circuit including: a core configured to extend along the cable when the magnetic probe is in use; flux-generating means for generating a magnetic flux in a section of the ferromagnetic part of the cable; and an air gap located in the core to create a point of zero magnetic field surrounded by a zone of low magnetic field, between the core and the central axis; and at least three magnetic sensors, each magnetic sensor being associated with at least one of the at least three magnetic circuits and located outside the core, in the low-magnetic-field zone, the at least three magnetic sensors being able to measure a low magnetic flux or a low variation in magnetic flux caused by the defects in the ferromagnetic part of the cable.

In some embodiments, the magnetic probe includes exactly three magnetic circuits and three associated magnetic sensors, equidistant from one another.

In some embodiments, two adjacent magnetic circuits are spaced apart by 120°, around the central axis of the frame.

In some embodiments, the core includes a longitudinal portion extending along the cable, when the probe is in use, and two tabs oriented radially towards the central axis; and the flux-generating means include a first magnet located in a first tab of the two tabs and a second magnet located in a second tab of the two tabs.

In some embodiments, the magnetic flux generated in the cable is below a magnetic saturation level of the cable when the magnetic probe is in use.

In some embodiments, the air gap of each circuit creates a magnetic field leakage at the center of the core in the opposite direction to the magnetic flux generated.

In some embodiments, the at least three magnetic sensors are ultra-sensitive sensors.

In some embodiments, the at least three magnetic sensors are sensors capable of measuring a magnetic flux of less than 5 mT.

In some embodiments, the at least three magnetic sensors each have an operating range of ±2.5 mT, and preferably an operating range minimally between ±1 mT.

In some embodiments, symmetrical positioning of the at least three magnetic sensors and averaging of the measurements compensate for cable displacements relative to the central axis of up to ±2 cm, limiting the error to a maximum of 2 μT.

In some embodiments, the magnetic probe includes one or more control modules, each including acquisition means, processing means and calculating means for acquiring and processing signals picked up by the at least three magnetic sensors, and for performing calculations from the processed signals.

In some embodiments, a symmetrical positioning of the at least three magnetic sensors reduces or eliminates the effect produced by a displacement of the cable relative to the central axis on the measurements made by the magnetic probe, the calculation means being configured to average the measurements of the at least three magnetic sensors or perform an equivalent operation.

In some embodiments, each control module includes means for recording and/or transmitting measurements or calculations made on the basis of measurements.

In some embodiments, each control module is configured to calculate magnetic surface losses (LMA) and/or identify broken strands (LF) from magnetic flux values or magnetic flux variations measured by at least one of the at least three magnetic sensors.

In some embodiments, each control module includes algorithmic means for reducing or suppressing the effect of a magnetic field generated by a current flowing in the cable under inspection, the cable in this case corresponding to an energized electrical conductor of a high-voltage transmission line.

In some embodiments, each control module is configured to calculate magnetic surface losses (MSL) from absolute measurements made by the magnetic sensors.

In some embodiments, the magnetic probe includes a linear encoder configured to be in contact with the cable to be inspected, each control module being configured to locate for broken strands (LF) from differential measurements made by the magnetic sensors or from absolute measurements read at regular intervals, the intervals being determined as a function of position readings obtained from the linear encoder.

In some embodiments, the magnetic probe includes a sensor for earth's gravitational field, each control module including algorithmic means for reducing or eliminating the effect of the earth's gravitational field on the magnetic flux measurements made by the at least three magnetic sensors.

In some embodiments, an opening of the magnetic probe corresponds to a transverse circular section around the central axis capable of receiving the cable between the at least three magnetic sensors of the magnetic probe, the ratio of the radius of the opening of the magnetic probe to the weight of the magnetic probe being of the order of 60 mm/kg.

In some embodiments, the at least three magnetic circuits and the at least three magnetic sensors are positioned and dimensioned to allow inspection of cable whose ferromagnetic portion has a diameter of between approximately 2 mm and approximately 50 mm.

In some embodiments, the at least three magnetic circuits and the at least three magnetic sensors are positioned and dimensioned to allow inspection of connecting sleeves of electrical conductors on high-voltage transmission lines, the ferromagnetic part including a section in the sleeves connecting the electrical conductors, and a transition zone between the conductors and the sleeves, in which the passage of the magnetic probe allows continuous measurement during relative movement between the magnetic probe and the sleeve.

In some embodiments, the at least three magnetic circuits and the at least three magnetic sensors are parameterized to enable inspection of the ferromagnetic core of ACSR-type conductors.

In some embodiments, the frame, the at least three magnetic circuits and the at least three sensors have a total mass of less than 2 kg, making the magnetic probe portable by drone or similar means of transport.

In some embodiments, the configuration of the passage in the frame enables the probe to be installed on a cable, by drone, without human intervention.

In some embodiments, the at least three magnetic sensors are of the flux gate, Hall effect or magnetoresistance type.

In some embodiments, the measurements made by the at least three magnetic sensors have a linear relationship with a geometric parameter of the ferromagnetic part of the cable, facilitating calibration of the magnetic probe.

In some embodiments, the passage includes a fixed, permanently open gap.

In some embodiments, the core and tabs each include a stack of mild steel laminations in a configuration that minimizes weight by optimizing shape to concentrate and uniform magnetic flux therein.

In some embodiments, the frame does not include an opening or closing mechanism for installing the magnetic probe on the cable.

In accordance with one aspect, there is provided a method for detecting defects in a ferromagnetic part of a cable, the method using the magnetic probe as described herein.

In accordance with one aspect, there is provided a system for detecting defects in a ferromagnetic part of a cable, the system including a magnetic probe as described herein; and transport means for moving the magnetic probe along the cable so as to collect measurements representative of potential defects in the ferromagnetic part of the cable.

The technology and its advantages will become clearer from the following non-limiting description of preferred embodiments of the technology, made with reference to the appended drawings.

### BRIEF DESCRIPTION OF THE FIGURES

FIG. 1 (prior art) illustrates continuous poles made of mild steel, and incorporating high-field magnets to create a magnetic field.

FIG. 2 (prior art) is a representation of the “magnetester” device.

FIG. 3 (prior art) shows an example of a conductor.

FIG. 4 illustrates an air gap in a magnetic circuit to create a zero magnetic field point, in accordance with one embodiment.

FIG. 5 is a side view of a magnetic probe, in accordance with one embodiment.

FIG. 6 is a front view of the magnetic probe of FIG. 5.

FIG. 7 is an example of a magnetic sensor, in accordance with an embodiment.

FIG. 8 illustrates a magnetic probe, according to one embodiment.

FIG. 9 illustrates a magnetic probe, according to one embodiment.

FIG. 10 illustrates a perspective view of the magnetic probe shown in FIG. 8.

FIG. 11 illustrates a side view of the magnetic probe shown in FIG. 9.

FIG. 12 illustrates a top view of the magnetic probe shown in FIG. 9.

FIG. 13 illustrates the magnetic probe shown in FIG. 9, into which a cable has been inserted.

FIG. 14 illustrates the ability of the magnetic probe to compensate for frame displacement.

FIGS. 15 TO 25 illustrate different results obtained with the magnetic probe.

### DETAILED DESCRIPTION

In the following description, similar components and/or features in the Figures are represented by the same reference numbers. In order not to clutter the Figures, certain elements are not identified on all figures if they have already been shown on previous Figures. The elements shown in the Figures are not necessarily to scale, and the emphasis is rather on clearly illustrating the elements and structures of the various embodiments presented below.

Furthermore, although the embodiments described and illustrated comprise various components, and although some of these components have certain geometric configurations, it is understood that the number of components and their geometries may vary, and should therefore not be taken in their restrictive sense, nor should they be interpreted in such a way as to limit the scope of the present technology. It should be understood, as will also be apparent to the person skilled in the art, that other suitable components, as well as other suitable geometric configurations, may be used for the present technology and corresponding parts of the present technology.

All technical and scientific terms and expressions used in the present description have the same definitions as those generally understood by the person skilled in the art in the present technology. Definitions of certain terms and expressions used are nevertheless provided below.

The term “about” as used herein means “approximately”, “in the region of”, “around” or any other expression having a similar meaning. For example, when the term “about” is used in connection with a numerical value, it could modify it above and/or below by a predetermined variation. In some examples, the predetermined variation is about 10% from the nominal value. This term can also take into account, for example, the experimental error of a measuring device, rounding and/or statistical deviations. Where an interval of values is mentioned in this application, the lower and upper bounds of the interval are, unless otherwise specified, always included in the definition.

The term “defect(s)”, as well as any similar or equivalent term, will be used in the context of the present disclosure to refer to certain types of loss of material or physical integrity in ferromagnetic materials, such as through loss of steel section (“LMA”), broken steel strands (“LF”) and broken connection sleeves of electrical conductors (such as ACSR-type electrical conductors).

The term “signal”, as well as any similar or equivalent term, represents a variation in any physical quantity. A signal can be analog or digital, and typically carries information. A signal can be continuous or discrete, and can have various characteristics such as, for example and without limitation, a period, an amplitude and a phase. For example, in the context of applications in electricity or involving the use of electricity, an electrical signal can be representative of a potential difference, the intensity of an electric current, the variation of an amplitude, the variation of a frequency, the variation of a phase and/or any other relevant physical quantity. It should be noted that the properties of a signal can be measured and that during a measurement, a sample represented by a data set is obtained. The data set is generally representative of the signal being measured. The “measurement time” represents the duration, which is generally finite, of the acquisition of a sample comprising a set of data. Following its acquisition, the signal (or the sample comprising a data set representative of the signal) can be processed. Signal “processing” typically includes a method, procedure and/or the use of technique(s) to confirm the presence (or absence) of defects, to pinpoint the location of one or more defects where appropriate, and/or to reveal certain physical characteristics relevant to the characterization of these defects. For example, in a general and non-limiting way, signal processing can include operations or a sequence of mathematical operations. These operations include, but are not limited to: control, filtering, compression, transmission, noise reduction, convolution, deconvolution, prediction, identification and/or classification, in addition to other basic mathematical operations (e.g., addition, subtraction, multiplication and/or division). Thus, signal processing typically makes it possible to obtain a property of a signal that can subsequently be associated with a physical quantity or variation thereof, which in turn can be associated with the presence or absence of defects in the ferromagnetic part of the inspected cable.

Some of the following terms (including similar, synonymous and equivalent terms) will be used in this disclosure:
“High accuracy” will mean that the error is below a threshold of 2%;
“Fast measurement” will mean that the bandwidth is greater than 30 KHz.
“Fine resolution” will mean that the resolution is less than 1 μT;
“Low offset” (or “offset”) will mean an offset of less than 10 μT;
“Low noise” will mean a noise spectral density of less than 10 nT/√Hz;
“Accurate gain” will mean that the error associated with gain is less than 0.05%; and
“Very low non-linearity” will mean that the linearity error is less than 0.1%.

The expressions “external radiation”, “external disturbances”, and any other similar or equivalent expression, represent electrical, magnetic or electromagnetic noise. Noise is understood here as a signal having an origin other or different than the signal associated with the defects being characterized by the techniques herein presented. For example, a signal associated with noise generally has different properties to a signal of fault(s) in a ferromagnetic part of a cable.

The apparatus(es), method(s) and system(s) described herein, or at least elements thereof, can be implemented in computer programs running on programmable computers (e.g., a microcontroller), each comprising at least one processor, a data storage system comprising, for example and without being limitative, volatile and non-volatile memory elements, at least one input device and at least one output device. In some examples, the programmable computer may be a programmable logic unit, a mainframe computer, a server and personal computer, a cloud computing system, a portable computer, a personal data assistant, a cell phone, a smart phone, a portable device, a tablet, an intelligent display device, a set-top box or a virtual reality device. Each program is preferably implemented in a high-level programming, procedural or object-oriented language for communicating with a computer system. However, programs can also be implemented in assembly language or machine language. In all cases, the language can be a compiled or interpreted language. Each of these computer programs is preferably stored on a storage medium or device readable by a general or special programmable computer for the configuration and operation of the computer when the storage medium or device is read by the computer to execute the procedures to be described in the current description. In some embodiments, the systems can be integrated with an operating system running on the programmable computer.

### Context

The Magnetic Flux Leakage (MFL) technique has been around for a long time. It has a multitude of applications in the detection of defects in ferromagnetic materials. The basic principle of MFL is based on the formation of a magnetic circuit between a magnetic probe and a sample or object under inspection (or at least a portion of the sample or object). The magnetic probe is adapted to produce a relatively high magnetic field, or at least one high enough to saturate the sample or object. In the presence of a defect, the magnetic flux locally changes path near the defect (it leaks), causing a decrease or increase in the field which is detected by appropriate detectors, such as magnetic detectors.

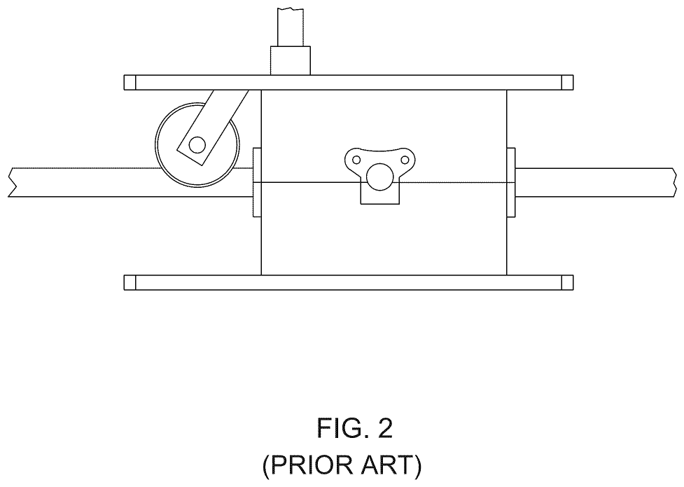

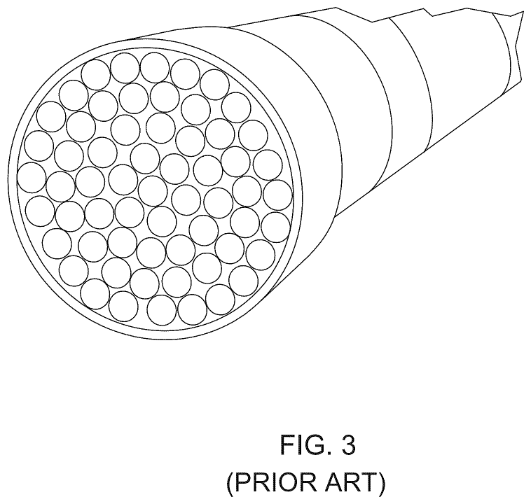

Various commercial solutions exist, such as, but not limited to:
1. The “Magnetester”, shown in FIG. 2 (PRIOR ART). This device has a mass of 23 kg and a maximum aperture of 44 mm, equivalent to an aperture/mass ratio of 1.9 mm/kg;
2. The “Intron”. This device has a mass of 3 kg and a maximum opening of 24 mm, equivalent to an opening/mass ratio of 8 mm/kg; and
3. The “Magnograph 3”. This device has a mass of 13 kg and a maximum aperture of 45 mm, equivalent to an aperture/mass ratio of 3.5 mm/kg.

The three non-limiting examples presented above suggest a trend for this type of probe. Indeed, for commercial solutions already available, probe aperture correlates with probe mass (i.e., the larger the aperture, the greater the mass), which is summarized by the aperture/mass ratio presented above for each of the devices. This trend can be explained by the need to magnetically saturate the sample or object being inspected. It should be noted that around 80% of Hydro-Québec's 35,000 km of high-voltage lines are larger than 24 mm in diameter, limiting the commercial solutions that can be employed, which also limits the conductors that can be inspected. In addition, the inspection of connection sleeves would be impossible with the examples of commercial solutions presented above.

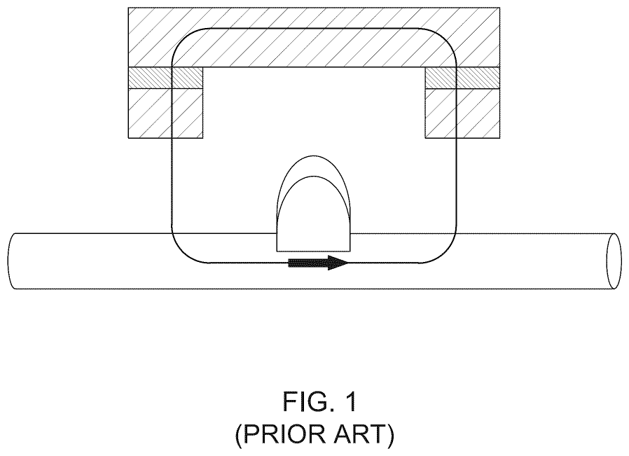

The configuration of the magnetic circuit is very similar from one probe to another. Existing solutions include probes with U-shaped poles. These poles are continuous and made of mild steel, and include high-field magnets (e.g., NdFeB) to create the magnetic field, as shown in FIG. 1 (PRIOR ART). Magnetic sensors are generally placed close to the magnetic circuit and in distinct locations in the various probes. However, whatever the choice of location, the magnetic sensors are in the presence of a non-zero magnetic field produced by the magnetic probe. Consequently, this configuration of existing solutions requires the use of a magnetic sensor with a wide dynamic range (e.g., a Hall-effect sensor). This configuration is therefore less sensitive and less accurate than a sensor with a smaller measurement range.

Existing magnetic probes use multiple poles to eliminate, or attempt to eliminate, the impact of cable/conductor displacement in the aperture. For example, among the existing solutions presented above, the Magnetester and Intron magnetic probes use 2 poles to reduce sensitivity to cable displacement along the gravitational axis. The Magnograph 3 probe uses 4 poles, which additionally reduces sensitivity to cable displacement in the axis perpendicular to the gravitational axis and to the cable axis. In

In all cases, the presence of 2 or 4 poles requires an opening and closing mechanism to install the magnetic probe around the cable to be inspected.

### Magnetic Probe, Method and System

The technology herein described concerns an ultra-light, wide-aperture magnetic probe for relatively accurate detection of steel section losses (“LMA”), broken steel strands (“LF”) and breaks in the connection sleeves of ACSR-type electrical conductors. Relatively accurate detection of these defects is possible despite the relatively low overall mass of the magnetic probe. In particular, the magnetic probe has a total mass of around 1.5 kg and an opening with a diameter of around 90 mm, equivalent to an opening/mass ratio of 60 mm/kg. These features enable the probe to be carried by drone, or similar means of transport, and to roll over connection sleeves and portion(s) of high-voltage cable, which is an improvement on the existing probes presented above. In fact, the aperture to mass ratio of the magnetic probe presented here is therefore around 7 times better than existing solutions. In addition, the magnetic probe herein described has a three-pole cylindrical symmetry, which eliminates or at least reduces the effect of conductor displacement on the measured signal, as well as eliminating the opening and closing mechanism. In addition, the creation of a zero magnetic field point (zero point) on each of the poles of the magnetic probe enables the use of ultra-sensitive magnetic sensors, and therefore, very accurate measurement, which is also an improvement over existing solutions.

The technology herein described outperforms probes currently available on the market in the precise application of steel cable inspection (which includes ACSR electrical conductors) on several levels. As will be described in greater detail below, the magnetic probe presented here measures LMA and relatively small LF defects with great accuracy, can be transported by drone or similar means of transport, can be deployed without an operator to open or close its passage, and has an opening large enough to inspect connection sleeves.

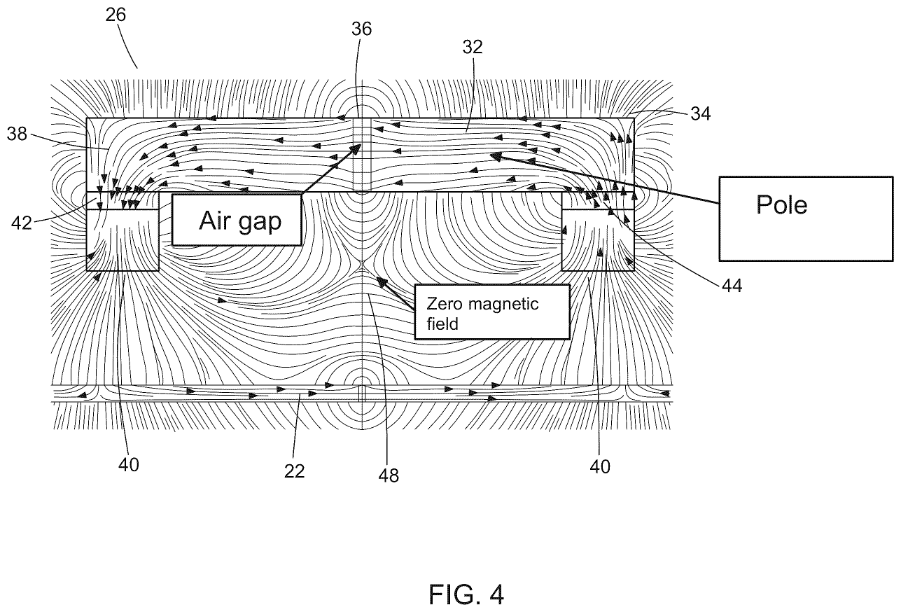

As will be described in more detail below, the magnetic probe relies on the introduction of an air gap in the magnetic circuit to create a point of zero magnetic field (“zero point”), three-pole symmetry and unsaturated operation of the magnetic probe, as illustrated, for example, on FIG. 4.

Existing MFL magnetic probes use seamless “U”-shaped poles, in which there is no place near the poles where the magnetic field is zero. In existing technologies, it is necessary to use wide-range magnetic sensors, which are generally not very accurate, so as not to saturate them. The introduction of an air gap in the middle of each magnetic pole of the probe creates a magnetic field leakage in the air in the middle of the poles. This magnetic field leakage is in the opposite direction to the magnetic field in air in the absence of an air gap. There is therefore certainly a point or region where the magnetic field is zero, the position of which depends on the probe's geometric parameters. It is then possible to use the full range of a more accurate magnetic sensor if the sensor is positioned close to this zero point. With the magnetic probe described here, it is therefore possible to measure relatively low or even very low magnetic fields, thus reducing the total mass of the magnetic probe and increasing the aperture diameter of the magnetic probe, while retaining the same precision in measuring LMA and LF defects. Increasing the aperture diameter enables inspection of large-diameter conductors and connecting sleeves, which was not possible with existing solutions.

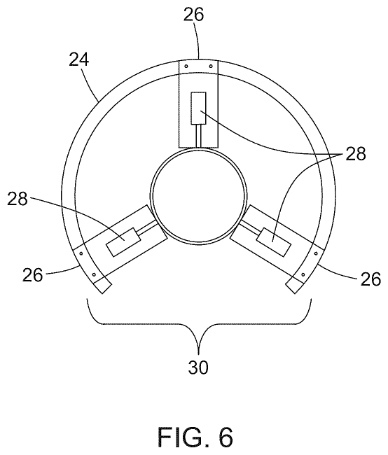

The use of a cylindrically symmetrical three-pole configuration enables a compensation for conductor displacement on two axes. For example, the three poles can be arranged at an angle of around 120° to each other. Note that in the illustrated configuration, poles 1 and 3 are attached to pole 2, but poles 1 and 3 are not attached to each other, leaving a passage at the bottom of the magnetic probe. This passage (see for example element 30 in FIG. 6) is adapted, positioned and dimensioned to insert the conductor without having to open and close the probe, or resort to a mechanism for opening and/or closing the magnetic probe. It is therefore not necessary for an operator to climb close to the conductor to close and open the probe, as is currently required using existing solutions. The magnetic probe can therefore be deposited by drone, or other similar means of transport, enabling rapid and safer deployment, reducing exposure to high voltages, which are potentially dangerous for operators.

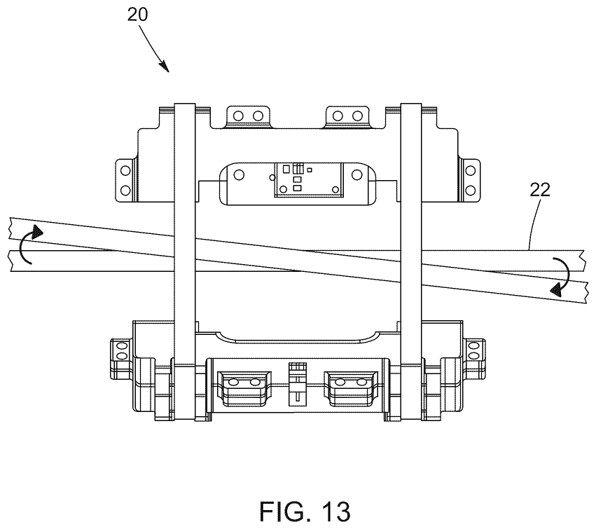

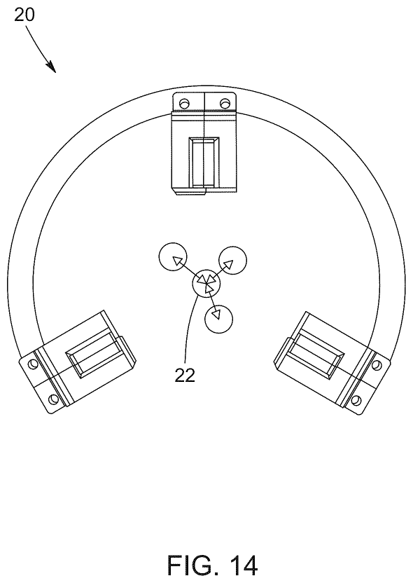

The principle of compensating for the conductor displacement by the magnetic probe will now be explained in more detail. In a scenario where the cable or a portion of the cable approaches pole 1, the amplitude of the signal detected by the magnetic sensor associated with pole 1 will change, while the amplitude of the signal respectively detected by the magnetic sensors associated with poles 2 and 3 will change away from pole 1. By averaging the signals on the three poles, these variations are almost completely cancelled out, making it possible to at least reduce and preferably eliminate significant signal variations, despite the displacement of the conductor (i.e., the relative movement of the conductor with respect to the position of the magnetic sensors). It should be noted that signal compensation or correction is only valid within a certain displacement limit, or more specifically a range of displacement values. For example, and without being limiting, for a magnetic probe with an aperture radius of 4.5 cm, the correction or signal compensation will be valid for a maximum displacement of approximately 2 cm. In practice, it is rare for a displacement to be greater than 2 cm. This range is therefore sufficient for the intended applications. In summary, the three-pole probe geometry reduces, and preferably eliminates, the signal variation caused by conductor displacement in relation to certain magnetic probe components, as illustrated non-limitatively in FIGS. 13 and 14.

In scientific literature, it is often mentioned that magnetic probes work or operate in the saturated regime. All existing magnetic probes for wire rope inspection appear to operate in the saturated regime. The magnetic probe herein described does not operate in saturated mode, which means that the weight of the magnetic probe can be greatly reduced. During the tests, there was no evidence to suggest that saturation is necessary or required for proper measurement. In fact, the magnetic probe herein presented can detect relatively small defects in unsaturated mode, thanks to the use of ultrasensitive sensors.

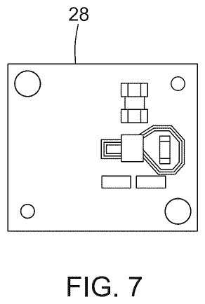

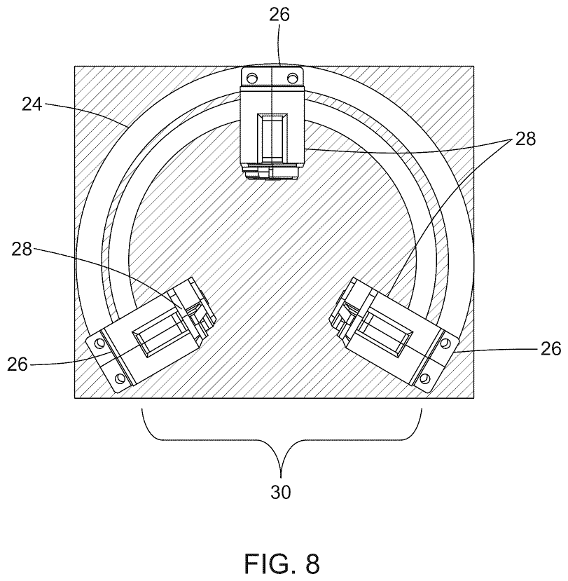

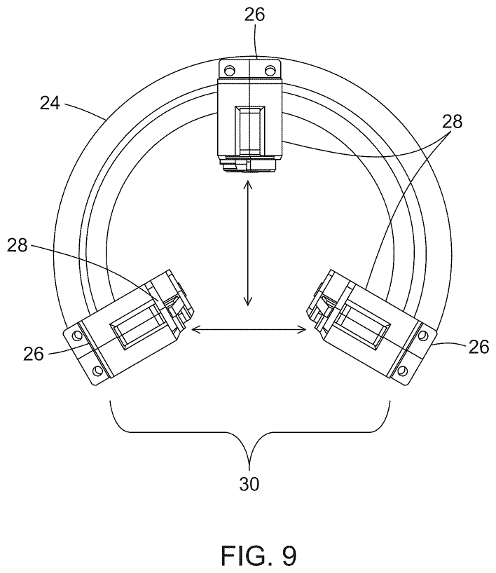

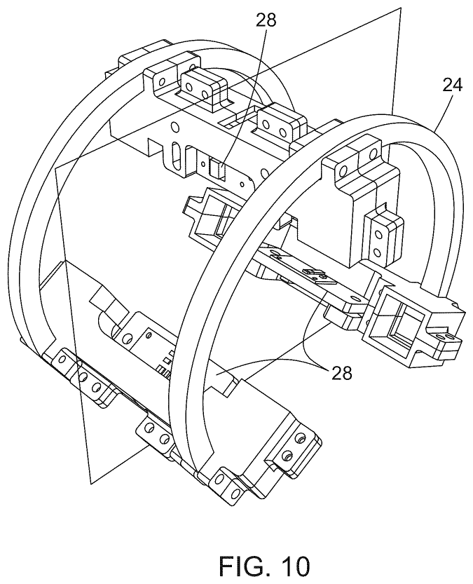

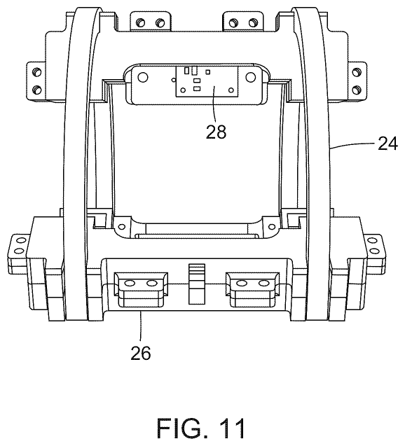

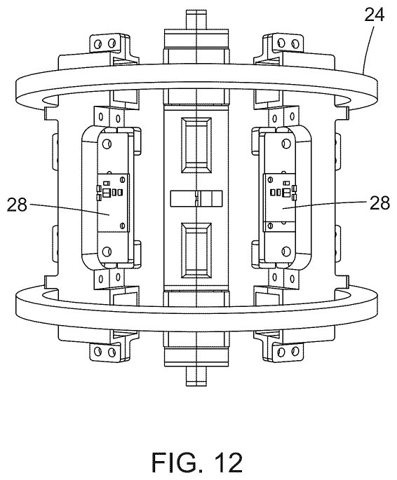

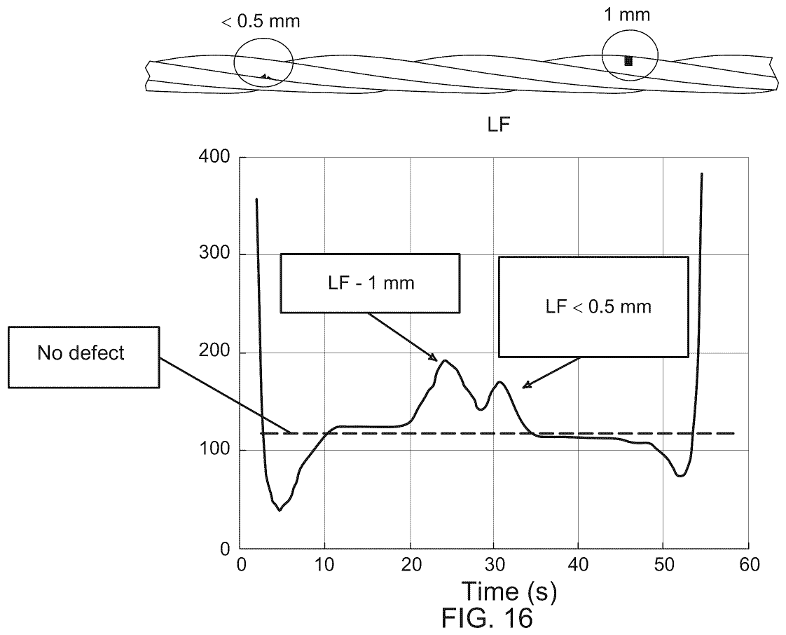

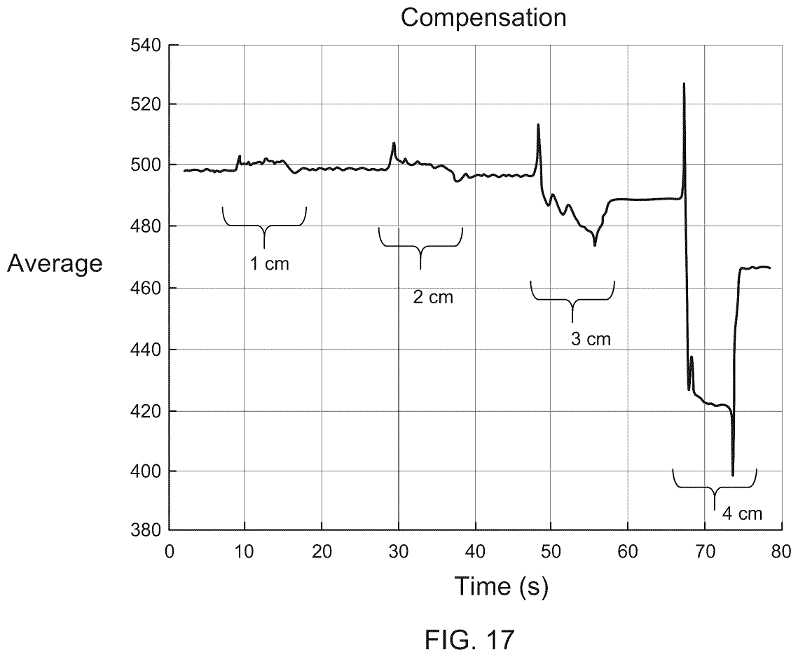

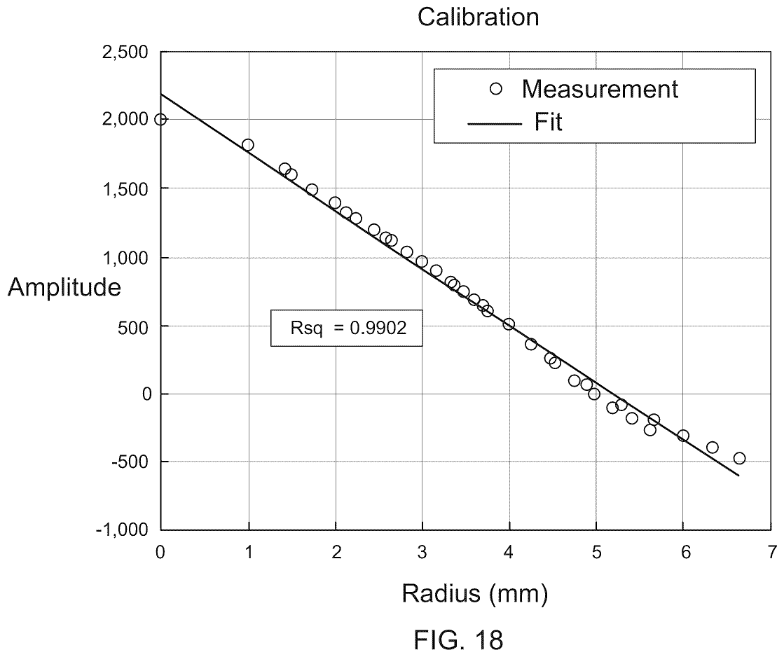

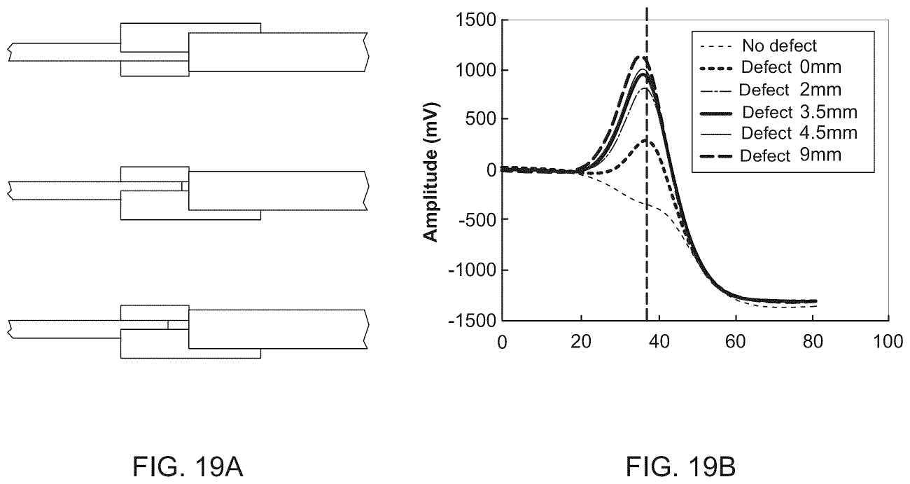

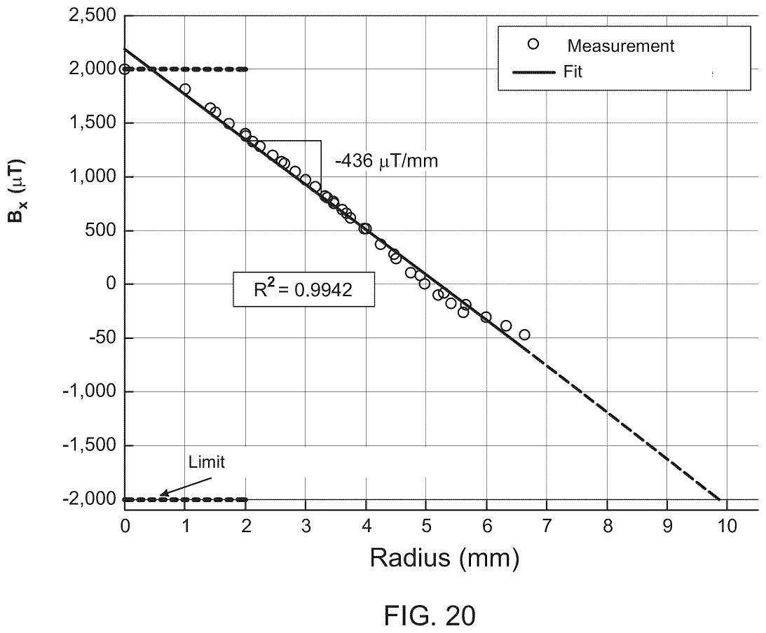

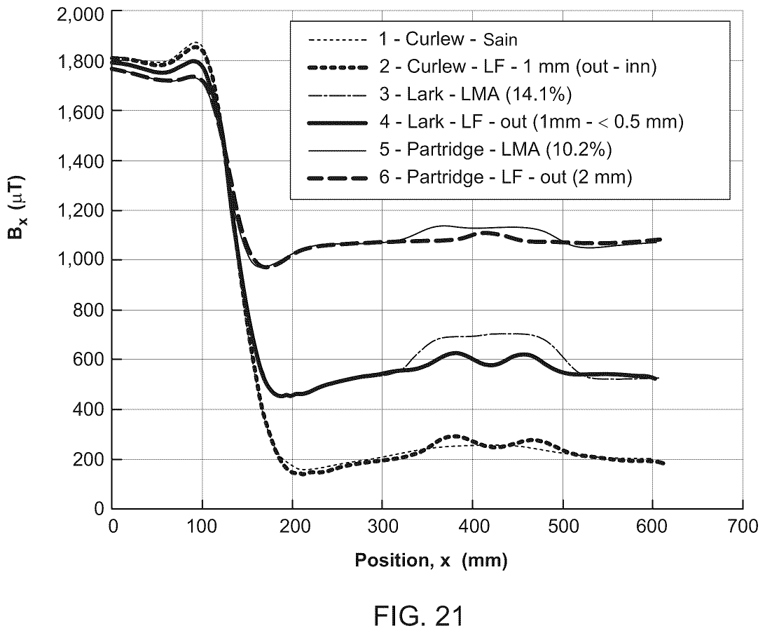

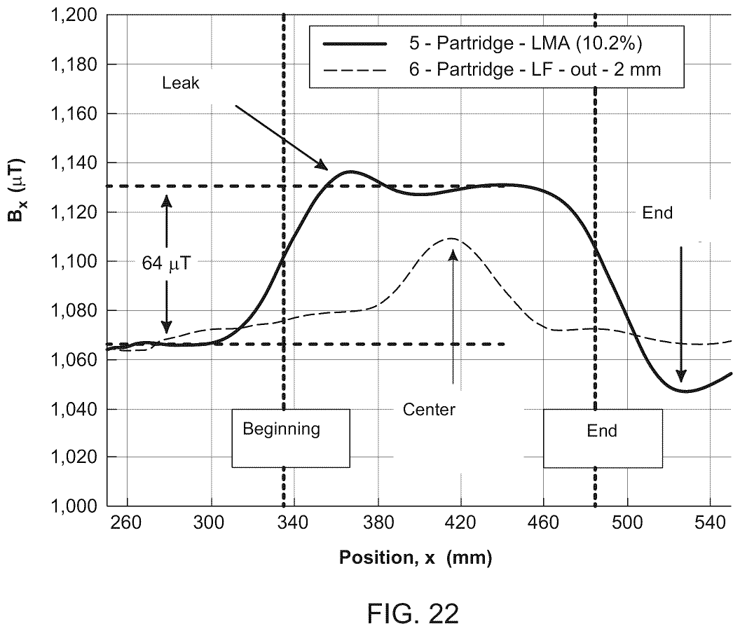

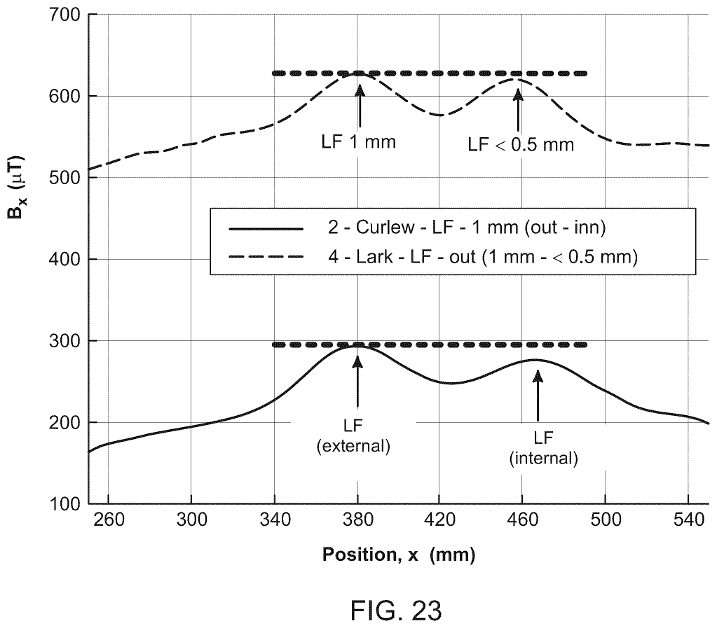

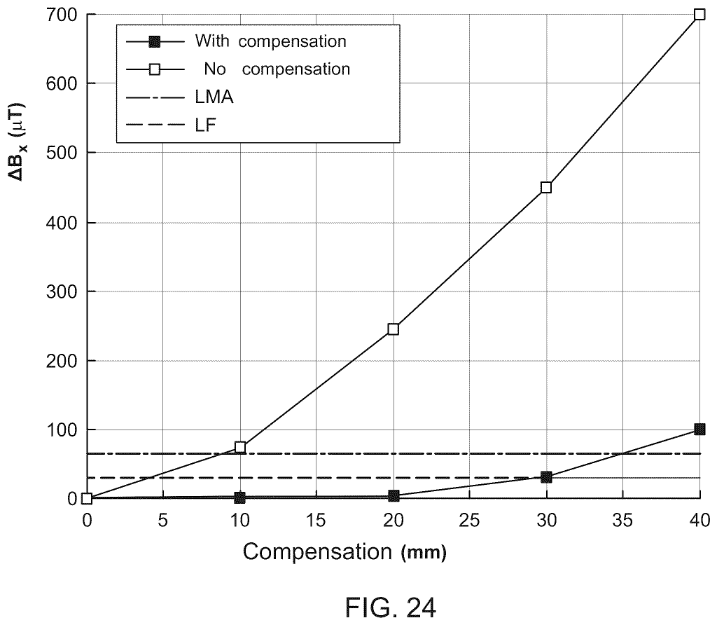

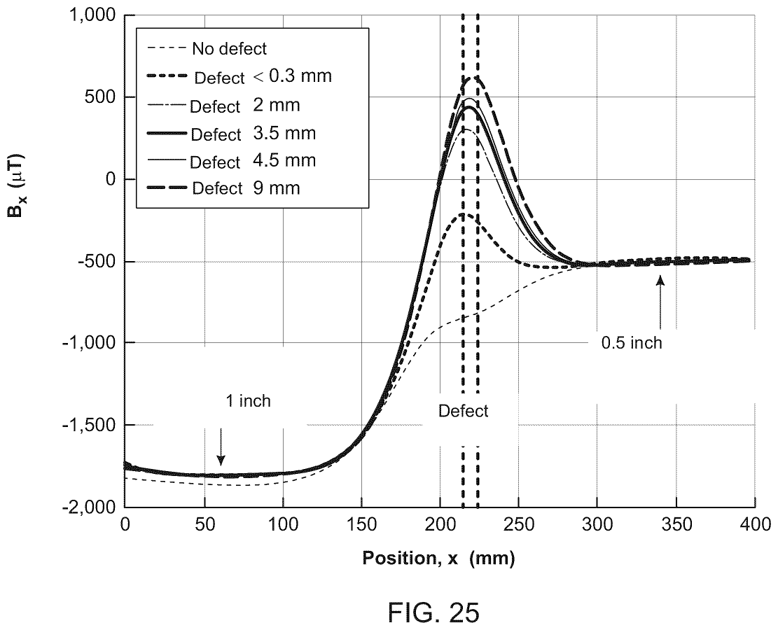

Now that the magnetic probe and its operating principle have been described from a general point of view, various embodiments of the technology will be presented, with reference to FIGS. 4 to 25.

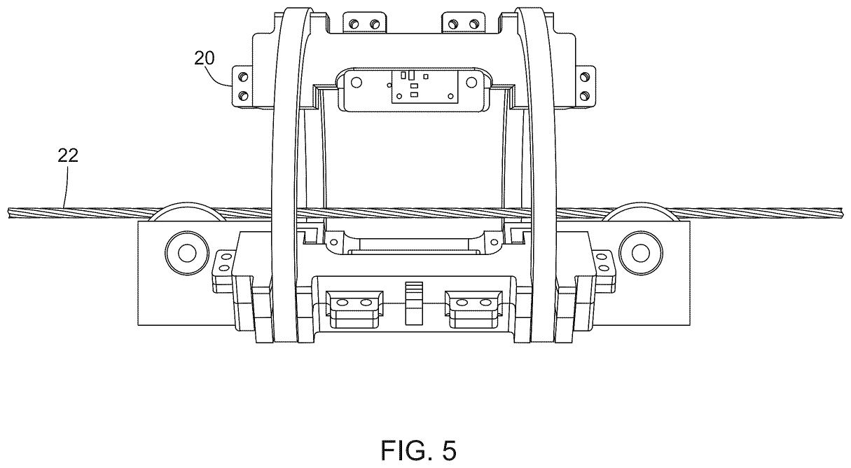

One embodiment of a magnetic probe 20 for detecting defects in a ferromagnetic part of a cable 22 is illustrated in FIG. 5.

The magnetic probe 20 includes a frame 24, at least three magnetic circuits 26 and at least three magnetic sensors 28. The frame 22 has a central axis and a passage 30 through which the cable 22 can pass or be inserted. The at least three magnetic circuits 26 (or simply the magnetic circuits 26) are held by the frame 24, spaced apart from each other. Note that the passage 30 allows the cable 22 to be inserted into the frame 24. Each magnetic circuit 26 includes a core 32 configured to extend along the cable 22 when the magnetic probe 20 is in use; means 34 for generating magnetic flux in a section of the ferromagnetic part of the cable 22; and an air gap 36 located in the core 32 to create a zero magnetic field point surrounded by a low magnetic field zone, between the core 32 and the central axis of the frame 24. Each magnetic sensor 28 is associated with at least one of the at least three magnetic circuits 26 and is located outside the core 32, in the low-magnetic-field zone. The at least three magnetic sensors 28 (or simply the magnetic sensors 28) are able to measure a low magnetic flux or a small variation in magnetic flux caused by defects in the ferromagnetic part of the cable 22.

In some embodiments, the magnetic probe 20 includes exactly three magnetic circuits 26 and exactly three associated magnetic sensors 28, equidistant from one another. In other embodiments, the magnetic probe may include four, five or six magnetic circuits.

In the illustrated configurations, two adjacent magnetic circuits 28 are spaced at an angle of 120° one from the other, around the central axis of the frame 24. Note that the angle depends on the number of magnetic circuits being mounted on the frame 24.

In some embodiments, the core 32 includes a longitudinal portion 38 extending along the cable 22, when the magnetic probe 20 is in use, and two tabs 40 oriented radially towards the central axis of the frame 22. The means 34 for generating the flux include a first magnet 42 located in a first tab of the two tabs 40 and a second magnet 44 located in a second tab of the two tabs 40.

In some embodiments, the magnetic flux generated in cable 22 is below a level of magnetic saturation of cable 22 when the magnetic probe 20 is in use, i.e., the magnetic probe is not operated in saturated mode.

The air gap 36 of each magnetic circuit 26 is adapted and configured to create a magnetic field leakage in the air 48 near the air gap 36 (i.e., in the air at the center of the circuit 26, and at the bottom of the core 32), in the opposite direction to the magnetic flux generated in the air 48 in the absence of air gap 32.

In some embodiments, the magnetic sensors 28 are ultra-sensitive sensors. For example, the magnetic sensors 28 may be sensors capable of measuring a magnetic flux of less than 5 mT. In some embodiments, the magnetic sensors 28 each have an operating range of ±2.5 mT, and preferably an operating range minimally included between ±1 mT. It should be noted that the magnetic probe 20 enables measurements that are relatively insensitive to gain or offset drift as a function of temperature.

As illustrated in some Figures, it is possible that a relative movement or displacement (e.g., radial displacement) between the magnetic probe 20 and the cable 22 needs to be compensated. In this respect, symmetrical positioning of the three magnetic sensors 28 and averaging the measurements taken by the magnetic sensors 28 can compensate for displacements of the cable 22 relative to the central axis of frame 24 up to ±2 cm, limiting the error to 2 μT at most. In this way, the potentially negative effect of the relative displacement of the cable 22 with respect to the magnetic probe 20 can be compensated, enabling measurements that are precise enough for the intended applications.

In some embodiments, the magnetic probe 20 includes one or more control modules, each including acquisition means, processing means and calculating means for acquiring and processing signals picked up by the magnetic sensors 28. The control modules enable calculations, including a plurality of mathematical operations, to be performed on the basis of the measured and processed signals. As previously mentioned, symmetrical positioning of the magnetic sensors 28 reduces or eliminates the effect of the cable 22 displacement relative to the central axis on measurements taken when the magnetic probe 20 is in use. The calculating means are configured to average the measurements of the magnetic sensors 28 or perform an equivalent operation. Each control module could include means for recording and/or transmitting measurements or calculations made on the basis of measurements. In some embodiments, each control module is configured to calculate magnetic section or surface losses (LMA) and/or to identify broken strands (LF) from magnetic flux values or magnetic flux variations measured by at least one of the magnetic sensors 28. In some embodiments, each control module includes algorithmic means for reducing or suppressing the effect of a magnetic field generated by a current flowing in the cable 22 under inspection, the cable 22 corresponding in this case to an energized electrical conductor of a high-voltage transmission line. In some embodiments, a magnetic field originating from the cable or a stray magnetic field may be an alternating magnetic field, and the algorithmic means for reducing or suppressing the effect of the alternating magnetic field generated by a current flowing in the cable under inspection include an algorithm for filtering a component at the frequency of a measured signal, or for synchronizing flux measurement readout times with times when the current flowing in the conductor passes through zero.

In some embodiments, each control module can be configured to calculate magnetic surface losses (MSLs) from absolute measurements (i.e., non-relative measurements) made by the magnetic sensors 28.

In some embodiments, the magnetic probe 20 includes a linear encoder 46 configured to contact the cable to be inspected, each control module being configured to locate for broken strands (LF) from differential measurements made by the magnetic sensors 28 or from absolute measurements read at regular intervals. The intervals are determined on the basis of position readings obtained from the linear encoder 46.

In some embodiments, the magnetic probe 20 includes a sensor for the earth's gravitational field, and each control module includes algorithmic means for reducing or suppressing the effect of the earth's gravitational field on the magnetic flux measurements made by the sensors.

In some embodiments, a magnetic probe aperture corresponds to a transverse circular section around the central axis that can accommodate the cable between the at least three magnetic sensors of the magnetic probe, the ratio of the radius of the magnetic probe aperture to the weight of the magnetic probe being of the order of 60 mm/kg. It should be noted that the aperture is the circular section at the center of the magnetic probe 20, around the central axis, where the cable 22 will be located during inspection.

In some embodiments, the magnetic circuits 26 and magnetic sensors 28 are positioned and sized to allow inspection of the cable 22 whose ferromagnetic portion has a diameter included between approximately 2 mm and approximately 50 mm. In some implementations, the diameter could be up to 15 mm, for example in the context of LF fault detection, up to 20 mm, for example in the context of LMA fault detection and up to 30 mm, for example in the context of sleeve corrosion detection.

In some embodiments, the magnetic circuits 26 and the magnetic sensors 28 are positioned and dimensioned to enable inspection of electrical conductor connection sleeves on high-voltage transmission lines, the ferromagnetic part including a section in the sleeves connecting the electrical conductors, and a transition zone between the conductors and the sleeves, in which the passage 30 of the frame 24 of the magnetic probe 20 enables continuous measurement to be taken during relative movement between the magnetic probe and the sleeve, relative movement being defined here as the magnetic probe 20 advances and progressively covers the sleeve, or conversely lets the sleeve come out of the magnetic probe 20.

In some embodiments, the magnetic circuits 26 and the magnetic sensors 28 are parameterized to enable inspection of the ferromagnetic core of ACSR-type conductors. For example, the magnetic circuits 26 and the magnetic sensors 28 can be optimized in their position and dimensions to enable inspection of the ferromagnetic core of ACSR-type conductors, as opposed to an all-steel cable of the same diameter.

In some embodiments, the frame 24, the magnetic circuits 26 and the magnetic sensors 28 have a total mass of less than 2 kg, making the magnetic probe 20 portable by a drone or similar means of transport.

In some embodiments, the configuration of the passage 30 in the frame 24 enables the magnetic probe 20 to be installed on the cable 22, by a drone, without human intervention, greatly simplifying the installation of the magnetic probe 20 on the cable 22.

In some embodiments, the magnetic sensors 28 are of the fluxgate, Hall-effect or magnetoresistance type.

In some embodiments, the measurements made by the magnetic sensors 28 have a linear relationship with a geometric parameter of the ferromagnetic part of the cable 22, facilitating the calibration of the magnetic probe 20. The geometric parameter could be a radius, diameter, cross-section or area.

In some embodiments, the passage 30 includes a fixed, permanently open gap.

In some embodiments, the core 32 and the tabs 40 each include a stack of mild steel laminations in a configuration that minimizes weight by optimizing shape to concentrate and uniform magnetic flux therein.

In some embodiments, the frame 24 does not include an opening or closing mechanism for installing the magnetic probe 20 on the cable 22.

According to one aspect, a method for detecting faults in a ferromagnetic part of a cable is provided. The method employs the magnetic probe as previously defined.

According to one aspect, a system for detecting defects in a ferromagnetic part of a cable is provided. The system includes a magnetic probe as previously defined and transport means for moving the magnetic probe along the cable so as to collect measurements representative of potential defects in the ferromagnetic part of the cable.

The technology herein presented is based on the combination of a large magnetic probe opening (90 mm diameter) and a low magnetic probe weight (1.5 kg). The technology is also based on the absence of a probe opening and closing mechanism, thanks to the three-pole symmetry. The technology also relies on the three-pole symmetry to compensate for conductor displacement on two axes. The technology is also based on the sensitivity of the probe, resulting in a strategic location for the ultra-sensitive magnetic sensors (±2.5 mT range) in a zero-field zone (zero point). More specifically, the magnetic probe includes the addition of an air gap in the magnetic circuit of the poles, the creation of a point of zero magnetic field (zero point) close to the inspected object, the use of an ultrasensitive, low-noise sensor close to the zero point, the measurement of the inspected object in the unsaturated regime and the use of three-pole symmetry. In particular, this configuration makes it possible to obtain an ultralight, ultrasensitive magnetic probe with a large aperture and no closing mechanism. The technology described here is particularly well suited to ACSR conductors. It could also be used for all-steel cables. Finally, the magnetic probe described here enables LMA and LF defects to be detected, in addition to being able to be transported by drone, to be deposited on the conductor without an operator to close it, and to pass through connection sleeves to inspect their defects.

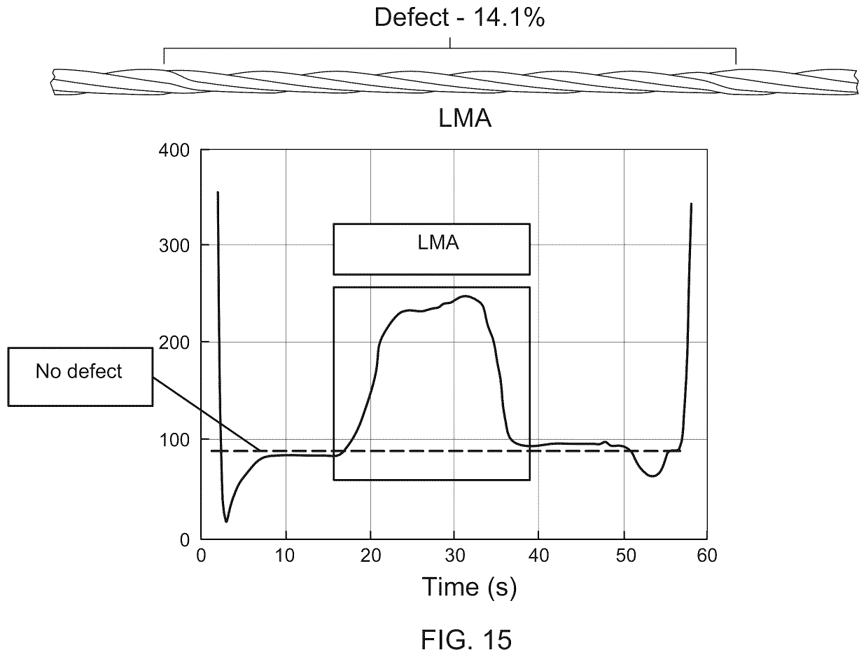

Non-limiting examples of results that can be achieved with the technology presented here are illustrated in FIGS. 15 to 25.

Although several preferred embodiments have been described in detail above and illustrated in the appended drawings, the technology is not limited to these embodiments alone. The skilled person will understand that the claims are not to be limited in scope by the preferred embodiments illustrated in the examples presented above but are to be given the broadest interpretation consistent with the description as a whole and the appended claims.

What is claimed is:

1. A magnetic probe for detecting defects in a ferromagnetic part of a cable, the magnetic probe comprising:
a frame having a central axis and a passage for passing the cable therethrough;
at least three magnetic circuits held by the frame, each being spaced apart from one another, each magnetic circuit comprising:
a core configured to extend along the cable when the magnetic probe is in use;
flux-generating means for generating a magnetic flux in a section of the ferromagnetic part of the cable; and
an air gap located in the core to create a point of zero magnetic field surrounded by a zone of low magnetic field, between the core and the central axis; and
at least three magnetic sensors, each magnetic sensor being associated with at least one of the at least three magnetic circuits and located outside the core, in the low-magnetic-field zone, the at least three magnetic sensors being able to measure a low magnetic flux or a low variation in magnetic flux caused by the defects in the ferromagnetic part of the cable.

2. The magnetic probe according to claim 1, comprising exactly three magnetic circuits and three associated magnetic sensors, equidistant from one another.

3. The magnetic probe according to claim 2, wherein two adjacent magnetic circuits are spaced apart by 120°, around the central axis of the frame.

4. The magnetic probe according to claim 1, wherein:
the core comprises a longitudinal portion extending along the cable, when the probe is in use, and two tabs oriented radially towards the central axis; and
the flux-generating means comprise a first magnet located in a first tab of the two tabs and a second magnet located in a second tab of the two tabs.

5. The magnetic probe according to claim 1,
wherein the magnetic flux generated in the cable is below a magnetic saturation level of the cable when the magnetic probe is in use.

6. The magnetic probe according to claim 1, wherein the air gap of each circuit creates a magnetic field leakage at the center of the core in the opposite direction to the magnetic flux generated.

7. (canceled)

8. The magnetic probe according to claim 1, wherein the at least three magnetic sensors are sensors capable of measuring a magnetic flux of less than 5 mT.

9. The magnetic probe according to claim 1, wherein the at least three magnetic sensors each have an operating range of ±2.5 mT, and preferably an operating range minimally between ±1 mT.

10. The magnetic probe according to claim 9, wherein symmetrical positioning of the at least three magnetic sensors and averaging of the measurements compensate for cable displacements relative to the central axis of up to ±2 cm, limiting the error to a maximum of 2 μT.

11. The magnetic probe according to claim 1, comprising one or more control modules, each comprising acquisition means, processing means and calculating means for acquiring and processing signals picked up by the at least three magnetic sensors, and for performing calculations from the processed signals.

12. The magnetic probe according to claim 1, wherein a symmetrical positioning of the at least three magnetic sensors reduces or eliminates the effect produced by a displacement of the cable relative to the central axis on the measurements made by the magnetic probe, the calculation means being configured to average the measurements of the at least three magnetic sensors or perform an equivalent operation.

13-16. (canceled)

17. The magnetic probe according to claim 11, wherein each control module is configured to calculate magnetic surface losses (MSL) from absolute measurements made by the magnetic sensors.

18. The magnetic probe according to claim 11, comprising a linear encoder configured to be in contact with the cable to be inspected, each control module being configured to locate for broken strands (LF) from differential measurements made by the magnetic sensors or from absolute measurements read at regular intervals, the intervals being determined as a function of position readings obtained from the linear encoder.

19. The magnetic probe according to claim 11, comprising a sensor for earth's gravitational field, each control module comprising algorithmic means for reducing or eliminating the effect of the earth's gravitational field on the magnetic flux measurements made by the at least three magnetic sensors.

20. The magnetic probe according to claim 1, wherein an opening of the magnetic probe corresponds to a transverse circular section around the central axis capable of receiving the cable between the at least three magnetic sensors of the magnetic probe, the ratio of the radius of the opening of the magnetic probe to the weight of the magnetic probe being of the order of 60 mm/kg.

21. The magnetic probe according to claim 1, wherein the at least three magnetic circuits and the at least three magnetic sensors are positioned and dimensioned to allow inspection of cable whose ferromagnetic portion has a diameter of between approximately 2 mm and approximately 50 mm.

22. The magnetic probe according to claim 1, wherein the at least three magnetic circuits and the at least three magnetic sensors are positioned and dimensioned to allow inspection of connecting sleeves of electrical conductors on high-voltage transmission lines, the ferromagnetic part comprising a section in the sleeves connecting the electrical conductors, and a transition zone between the conductors and the sleeves, in which the passage of the magnetic probe allows continuous measurement during relative movement between the magnetic probe and the sleeve.

23. (canceled)

24. The magnetic probe according to claim 1, wherein the frame, the at least three magnetic circuits and the at least three sensors have a total mass of less than 2 kg, making the magnetic probe portable by drone or similar means of transport.

25. (canceled)

26. The magnetic probe according to claim 1, wherein the at least three magnetic sensors are of the flux gate, Hall effect or magnetoresistance type.

27. The magnetic probe according to claim 1, wherein the measurements made by the at least three magnetic sensors have a linear relationship with a geometric parameter of the ferromagnetic part of the cable, facilitating calibration of the magnetic probe.

28. The magnetic probe according to claim 1, wherein the passage comprises a fixed, permanently open gap.

29. The magnetic probe according to claim 4, wherein the core and tabs each comprise a stack of mild steel laminations in a configuration that minimizes weight by optimizing shape to concentrate and uniform magnetic flux therein.

30-31. (canceled)

32. A system for detecting defects in a ferromagnetic part of a cable, the system comprising:
a magnetic probe according to claim 1; and
transport means for moving the magnetic probe along the cable so as to collect measurements representative of potential defects in the ferromagnetic part of the cable.
